(19) United States
(12) Patent Application Publication
(10) Pub. No.: US 2024/0194603 A1
(43) Pub. Date: Jun. 13, 2024

(54) SEMICONDUCTOR DEVICE INCLUDING FILLER CELL

(71) Applicant: Samsung Electronics Co., Ltd., Suwon-si (KR)

(72) Inventor: Seungju Hwang, Suwon-si (KR)

(21) Appl. No.: 18/533,719

(22) Filed: Dec. 8, 2023

(30) Foreign Application Priority Data
Dec. 8, 2022 (KR) 10-2022-0170955

(51) Int. Cl. H01L 23/528

(52) U.S. Cl. CPC H01L 23/5286

(57) ABSTRACT

A semiconductor device includes a plurality of logic cells disposed in a first direction, a plurality of filler cells disposed in the first direction, and a power rail configured to apply a voltage to the logic cells and the filler cells, wherein the power rail extending in the first direction and electrically connected to the plurality of logic cells, and a reinforcement pattern disposed in at least one of the plurality of filler cells and electrically connected to the power rail, wherein the reinforcement pattern is electrically connected to the power rail at a plurality of distinct points.

### CROSS-REFERENCE TO RELATED APPLICATION

This application is based on and claims priority under 35 U.S.C. § 119 to Korean Patent Application No. 10-2022-0170955, filed on Dec. 8, 2022, in the Korean Intellectual Property Office, the disclosure of which is incorporated by reference herein in its entirety.

### TECHNICAL FIELD

The inventive concept relates to a semiconductor device, and more particularly, to a semiconductor device including a filler cell.

### DESCRIPTION OF RELATED ART

Electrical power needs to be distributed throughout an integrated circuit. The power may be distributed by wire lines formed of metal. As fabrication technologies have become smaller and a degree of integration of the integrated circuit has increased, the width of the wire lines has also been reduced, while the length of the wires lines has not changed significantly. Under these conditions, there has been an increase in resistance per unit length of the wire lines, which may cause a problem of power loss.

In some cases the degree of integration of the integrated circuit has been increased by reducing a height of a cell thereof. Accordingly, a width of a power rail supplying power to elements in an integrated circuit may be reduced. As a result, the resistance of the power rail may increase, and problems such as power loss due to voltage drop or malfunction of the device, may occur.

### SUMMARY

Some inventive concepts provide a semiconductor device capable of compensating for power loss over a power rail in high integration devices and preventing a malfunction of elements in an integrated circuit.

According to an aspect of the inventive concepts, there is provided a semiconductor device including a plurality of logic cells disposed in a first direction, a plurality of filler cells disposed in the first direction, and a power rail configured to apply a voltage to the logic cells and the filler cells, wherein the power rail extending in the first direction and electrically connected to the plurality of logic cells, and a reinforcement pattern disposed in at least one of the plurality of filler cells and electrically connected to the power rail, wherein the reinforcement pattern is electrically connected to the power rail at a plurality of distinct points.

According to another aspect of the inventive concepts, there is provided a semiconductor device including a plurality of logic cells disposed in a first direction, a plurality of filler cells disposed in the first direction, and a power rail extending in the first direction and electrically connected to the plurality of logic cells, wherein a width of a first portion of the power rail corresponding to at least one filler cell among the plurality of filler cells in a second direction perpendicular to the first direction is greater than a width of a second portion of the power rail corresponding to the plurality of logic cells in the second direction, wherein the at least one filler cell includes a reinforcement pattern including an empty space, wherein the reinforcement pattern is electrically connected to the power rail.

According to another aspect of the inventive concepts, there is provided a semiconductor device including a plurality of logic cells extending in a first direction, a plurality of filler cells extending in the first direction, and a first power rail extending in the first direction and configured to apply a first voltage to the plurality of logic cells, a second power rail extending in the first direction, spaced apart from the first power rail in a second direction perpendicular to the first direction, and configured to apply a second voltage to the plurality of logic cells, wherein the plurality of logic cells and the plurality of filler cells are disposed between the first power rail and the second power rail, in the first direction, wherein at least one filler cell among the plurality of filler cells includes at least one reinforcement, wherein the at least one reinforcement pattern is electrically connected to one of the first power rail and the second power rail at a plurality of distinct points.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor device according to an embodiment;

FIG. 2 is a plan view illustrating a logic cell of a semiconductor device according to an embodiment;

FIG. 3 is a plan view for explaining a filler cell according to an embodiment;

FIG. 4 is a plan view illustrating the structure of a filler cell according to an embodiment;

FIG. 5 is a plan view illustrating another structure of a filler cell according to an embodiment;

FIG. 6 is a plan view illustrating structures of a power rail and a filler cell according to an embodiment;

FIG. 7A and FIG. 7B are plan views for explaining a filler cell including a dummy pattern according to an embodiment;

FIG. 8 is a diagram illustrating a structure of layers of a semiconductor device according to an embodiment;

FIG. 9 is a plan view illustrating stacked cells according to an embodiment;

FIG. 10 is a plan view illustrating a semiconductor device having a stacked structure according to an embodiment; and

FIG. 11 is a plan view illustrating a logic cell including a transistor configuration according to an embodiment.

### DETAILED DESCRIPTION

Hereinafter, embodiments of the inventive concepts will be described in detail with reference to the accompanying drawings.

Standard cell-based circuit design is a methodology for designing integrated circuits (ICs). Standard cell-based circuit design is a structured approach that combines pre-designed standard cells to create complex semiconductor circuits. More particularly, one or more standard cells may be registered in a computer system after being designed and verified. These standard cells may be elements, such as logic gates, that may be used repetitively in a process of generating a layout design of an integrated circuit.

The generation of the layout design may include determining the placement of these standard cells. The use of the standard cell may reduce the time needed for generating the layout design. For example, characteristics such as logic design, arrangement, wiring, and the like, may be standardized, which may improve the performance of computer aided design (CAD) when generating the layout design.

Standard cells may include, for example, cells for performing discrete functions, such as an AND, an OR, a NOR, and inverters, and cells for preforming more complex functions, such as an OR/AND/INVERTER (OAI) and an AND/OR/INVERTER (AOI). Standard cells may include other elements, such as a storage element implemented as a latch pair flip-flop or a latch. As the design of the semiconductor circuits becomes more sophisticated and complicated, the time and cost needed to produce a layout design may be increased, even with the use of CAD.

Standard cells typically have a constant cell height, and an integrated circuit may be designed by arranging appropriate standard cells in a plurality of columns. Specifically, when designing the integrated circuit, if standard cells or logic circuit blocks of a certain size may be already stored in a library of the computer system, a standard cell suitable for a design purpose may be retrieved from the library and placed in the layout design as a plurality of cells on a chip.

The design of the integrated circuit may include the determination of a wiring layout, in which wiring length may be reduced or optimized for a wiring space between the cells. In general, if a transistor size included in each standard cell is reduced, the size of the standard cell may be reduced. For example, integrated circuits formed in the logic cell 100 may be designed using the standard cell method. As such, the standard cell may be used to increase a degree of integration of a semiconductor device.

As a size of the cells is reduced to increase the degree of integration, a size of power rails supplying power to the cells may also be reduced. For example, a width or cross-sectional area of the power rails may be reduced. As the size of the power rail decreases, resistance may increase due to IR drop, and a power loss occurring during voltage supply may also increase. According to some aspects, an improved power rail may be provided, which may mitigate the power loss associated with reduced size.

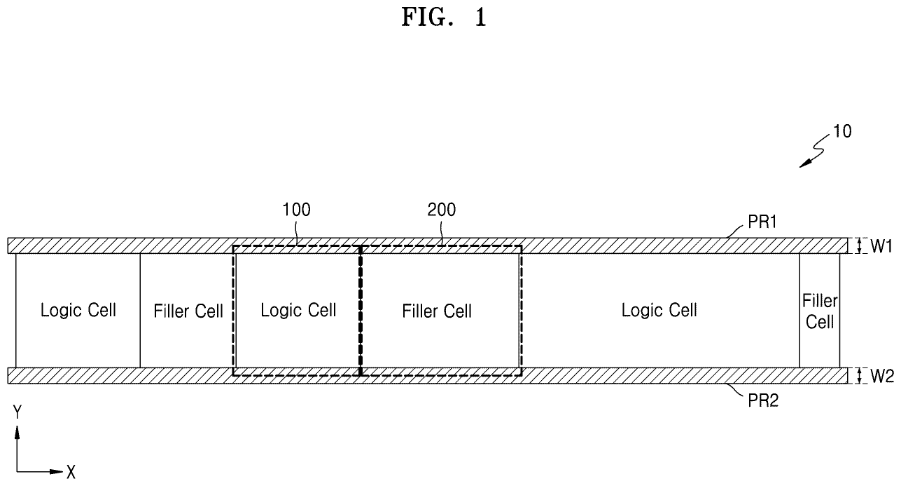

FIG. 1 is a plan view illustrating a semiconductor device according to an embodiment.

Referring to FIG. 1, a semiconductor device 10 may include a logic cell 100, a filler cell 200, a first power rail PR1, and a second power rail PR2. The logic cell 100 may include various semiconductor elements. In some embodiments, the logic cell 100 may be a unit for performing a certain function of the semiconductor device 10. The logic cell 100 may be disposed in a memory area, an input/output area, or the like. In addition, the filler cell 200 may be implemented for making an overall pattern density of the layout more uniform.

The filler cell 200 may be a cell disposed around the logic cell 100. For example, the filler cell 200 may be adjacent to the logic cell 100. In a process for manufacturing semiconductor elements disposed in the logic cell 100, uniform process conditions may be maintained for the entire wafer or substrate through the inclusion of the filler cell 200. The filler cell 200 may be an additional region that helps improve the uniformity and function of the semiconductor elements of the logic cell 100. In some aspects, the filler cell 200 may fill a space between standard cells. The filler cell 200 may be used to maintain uniform spacing between standard cells. Since the filler cell 200 may be electrically separated (e.g., insulated) from the semiconductor elements disposed in the logic cell 100, the filler cell 200 may be implemented so as not to directly affect the functions of the elements in the semiconductor device 10. For example, the filler cell 200 may contribute to forming a more uniform and functionally improved instance of the logic cell 100 in a Front End Of Line (FEOL) process.

In some embodiments, a chemical mechanical polishing (CMP) process may be performed on a wafer or substrate to achieve a planarized surface. When circuit patterns, such as shallow trench isolation (STI) features or metal lines, are not uniformly disposed on the wafer or substrate, the planarization effect of the CMP process may be reduced or deteriorated. Accordingly, dummy patterns may be arranged to improve the effect of the CMP process. For example, the dummy patterns may be arranged around the logic cell 100. The dummy pattern may be implemented as the filler cell 200.

In a process of manufacturing a semiconductor circuit, a thermal annealing process may be performed at various stages. For example, a thermal annealing process may be performed after an ion implantation process, or a rapid thermal annealing (RTA) may be performed to reduce defects and activate doped ions. In a case where a wafer or substrate is not uniform, an effect of the heat treatment may vary at different locations on or in the wafer or substrate, and accordingly, electrical characteristics of elements in the circuit may vary at different positions. For example, when the heat treatment temperature is lower or higher than an expected temperature at a certain location, a threshold voltage and a saturation current of a Field Effect Transistor (FET) may be out of specification. According to some aspects, dummy patterns may be used to achieve a uniform heat treatment effect through improved uniformity of the wafer or substrate. Dummy patterns may be included in the filler cell 200. The dummy patterns may be formed around the logic cell 100. The dummy patterns may not be electrically connected to circuits within the logic cell 100. The dummy patterns may be electrically insulated from the circuits within the logic cell 100. Accordingly, the dummy patterns may not perform a direct electrical function within the circuit.

In the semiconductor device 10 according to an embodiment, the filler cell 200 may include dummy patterns having a similar shape and pattern density to patterns disposed in the logic cell 100. Specifically, integrated circuits in the semiconductor device 10 may be designed and placed in the logic cell 100 based on the standard cell as described herein and the filler cell 200 may include dummy patterns designed and arranged based on the standard cell. Thus, the dummy patterns may have substantially the same shape and/or pattern density as patterns of the integrated circuit of the logic cell 100.

Although logic cells and filler cells are shown in an arrayed form crossing each other in FIG. 1, the structure of the semiconductor device 10 is not limited thereto. That is, cells including the logic cell 100 and the filler cell 200 may be disposed in various structures and shapes according to an electronic device to be implemented. The first power rail PR1 and the second power rail PR2 may conduct a power supply voltage or a reference voltage (e.g., ground voltage). For example, the first power rail PR1 may conduct the power supply voltage and the second power rail PR2 may conduct the reference voltage. As shown, the first power rail PR1 and the second power rail PR2 may extend in parallel in a first direction X. The first power rail PR1 and the second power rail PR2 may be spaced apart from each other in a second direction Y. A width W1 of the first power rail PR1 in the second direction Y perpendicular to the first direction X may be different than a width W2 of the second power rail PR2 in the second direction Y. For example, to compensate for the voltage drop caused by the increase in resistance due to the decrease in power rail size, as described herein, the width of the power rails may be increased, or the cross-sectional area of a channel through which the current flows may be increased by including a reinforcement pattern in the filler cell.

At least one cell may be disposed between the first power rail PR1 and the second power rail PR2. As described herein, each of the logic cells may be a cell for receiving a voltage from a power rail and performing a certain function in a device, and may be based on a standard cell. For example, each of the logic cells may implement a logic element (e.g., an AND, an OR, an XOR, an XNOR, an inverter, etc.) that performs a certain function. Each of the logic cells may include transistors constituting a logic element and wirings connecting the transistors to each other. Each of the filler cells may serve as a dummy cell, and fill an empty space between the logic cells arranged according to the designed circuit. In other words, filler cells may not perform a function in terms of circuitry.

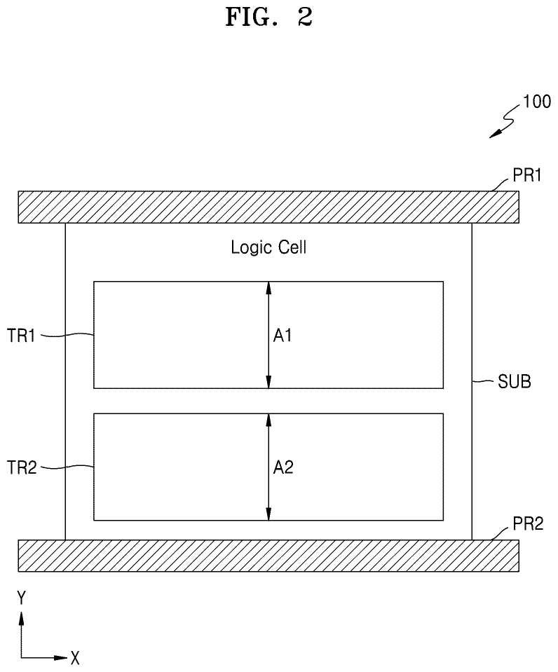

FIG. 2 is a plan view illustrating a logic cell of a semiconductor device according to an embodiment.

Referring to FIG. 1 and FIG. 2, the logic cell 100 of FIG. 1 may be provided. In some aspects, a first power rail PR1 and a second power rail PR2 may be provided on a substrate SUB, and a logic cell 100 may be defined between the first power rail PR1 and the second power rail PR2. In some embodiments, the logic cell 100 may include a first transistor region TR1 and a second transistor region TR2. For example, the first transistor region TR1 may be a P-channel Metal Oxide Semiconductor Field Effect Transistor (PMOSFET), and the second transistor region TR2 may be an N-channel Metal Oxide Semiconductor Field Effect Transistor (NMOSFET). In other words, the logic cell 100 may have a Complementary Metal-Oxide-Semiconductor (CMOS) structure provided between the first power rail PR1 and the second power rail PR2.

The first transistor region TR1 and the second transistor region TR2 may have a first height A1 and a second height A2 in the second direction Y, respectively. The height of the logic cell 100 may be substantially the same as a distance (e.g., pitch) between the first power rail PR1 and the second power rail PR2.

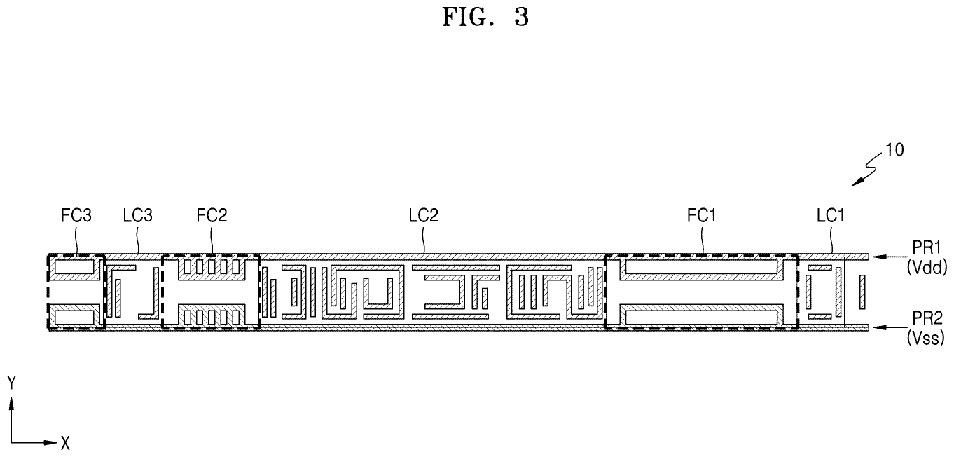

FIG. 3 is a plan view for explaining a filler cell according to an embodiment.

Referring to FIG. 3, the semiconductor device 10 may include a plurality of logic cells LC1, LC2, and LC3, a plurality of filler cells FC1, FC2, and FC3, a first power rail PR1, and a second power rail PR2. For example, a power voltage Vdd may be supplied through the first power rail PR1 and a ground voltage Vss may be supplied through the second power rail PR2.

As described herein, each of the plurality of logic cells LC1, LC2, and LC3 may be a logic element that performs a certain function in the semiconductor device, and a plurality of filler cells FC1, FC2, and FC3 may be arranged to improve process and performance effects of the semiconductor device 10. For example, the plurality of filler cells FC1, FC2, and FC3 may improve uniformity and performance of logic elements included in the plurality of logic cells LC1, LC2, and LC3. The plurality of filler cells FC1, FC2, and FC3 may reduce power loss in the semiconductor device 10. Further, the plurality of filler cells FC1, FC2, and FC3 may fill spaces in semiconductor device 10 for spacing between the plurality of logic cells LC1, LC2, and LC3. As described herein, to compensate for a voltage drop caused by an increase in resistance due to a decrease in the size of a power rail, a power rail may be reinforced, or a reinforcement pattern may be added to cells.

Since the plurality of logic cells LC1, LC2, and LC3 may be needed for the function of the semiconductor device 10, reinforcing a power rail or adding a reinforcement pattern within the logic cells may violate design rules or affect device performance. According to some aspects, the plurality of filler cells FC1, FC2, and FC3 may be used to by reinforce the power rail, or a reinforcement pattern may be added to the plurality of filler cells FC1, FC2, and FC3, and thereby it may be possible to reduce a voltage drop across the power rail. In some embodiments, each of the plurality of filler cells FC1, FC2, and FC3 may be a filler cell mitigating a voltage drop phenomenon.

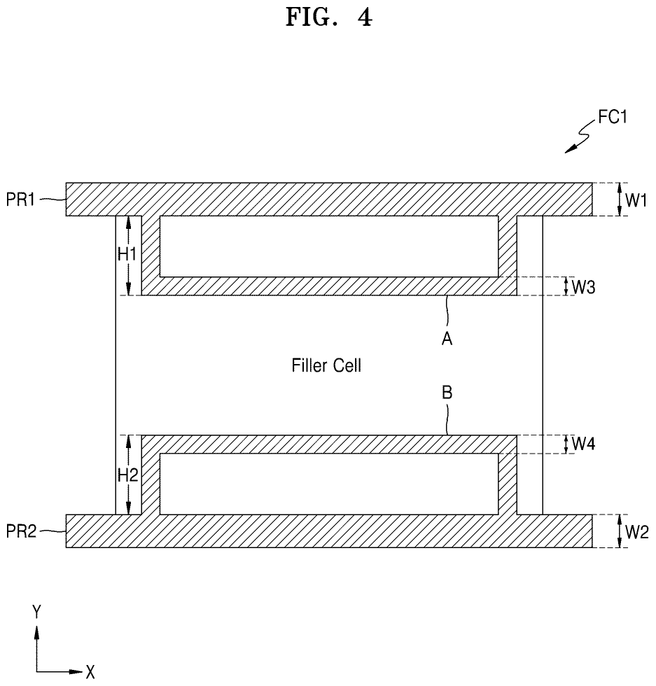

FIG. 4 is a plan view illustrating the structure of a filler cell according to an embodiment.

Referring to FIG. 4, the first filler cell FC1 may be disposed between the first power rail PR1 and the second power rail PR2. The first power rail PR1 and the second power rail PR2 may extend in parallel in the first direction X. The first power rail PR1 may have a first width W1 the second direction Y and the second power rail PR2 may have a second width W2 the second direction Y.

The first width W1 and/or the second width W2 may be reduced to integrate a greater number of elements as described herein. When the width of the power rail is reduced, the cross-sectional area of the power rail through which current flows may be reduced, and a resistance of the power rail may increase. That is, the degree of IR drop may be increased, and a power loss in a power rail may increase. Further, a device may malfunction due to insufficient voltage being supplied to elements. To solve this problem, when reinforcement patterns are placed on or in the filler cells, the cross-sectional area of the channel through which the current flows may be increased. In some embodiments, the first filler cell FC1 may include a first reinforcement pattern A. As shown, the first reinforcement pattern A may form a rectangular shape including an empty space. For example, the first reinforcement pattern A may be electrically connected to the first power rail PR1 at two distinct points, which may thereby form the empty space. The rectangular shape formed by the first reinforcement pattern A may have a first height H1 in the second direction Y. The first reinforcement pattern A may have a third width W3 in the second direction Y. For example, the empty space between the first reinforcement pattern A and the first power rail PR1 may have form the rectangular shape. Also, the first reinforcement pattern A of the first filler cell FC1 may be formed to contact the first power rail PR1, and may be electrically connected to the first power rail PR1. In this case, a size of the first power rail PR1 that may conduct a current may be increased by the third width W3, in addition to the first width W1 of the first power rail PR1. That is, the first reinforcement pattern A connected to the first power rail PR1 of the first filler cell FC1 may increase the cross-sectional area of the channel of the first power rail PR1.

Since the cross-sectional area of the channel through which current flows may be increased, a resistance of the power rail may be decreased and the IR drop phenomenon, which is a phenomenon in which voltage drops due to resistance, may be alleviated. Since the magnitude of the voltage drop may be reduced and power may be uniformly supplied to elements in the circuit, a malfunction of the device may be prevented. In addition, when the voltage drop is mitigated, the power supply voltage Vdd supplied to the circuit may be lowered, and power consumed in the circuit may be reduced and/or an efficiency of the circuit may be increased.

According to some aspects, improvements in process and design may be achieved by providing a reinforcement pattern in a filler cell, for example, the first reinforcement pattern A in the first filler cell FC1. For example, in a case where a power rail is reinforced, but does not include an empty space, a width of a channel may be the first height H1., In this case, patterns adjacent to a reinforced portion of the power rail may be affected. For example, when an exposure process is performed, a pattern without an empty space may be weakened in a periphery thereof, and an operation of the cells may be adversely affected. Therefore, a thickened pattern without an empty space may cause a malfunction of the device or deterioration of the performance of the device. Further, when such a thickened pattern is formed, adjacent patterns may need to be spaced further apart. Moreover, additional space may be needed to comply with design rules. As a result, in the case where a power rail is reinforced, but does not include an empty space, operating patterns (e.g., logic cell patterns) may not be located in positions originally determined in a layout design, or the degree of integration of circuits may decrease as the patterns are spaced apart.

According to some embodiments, a reinforcement pattern included in the filler cell having an empty space may have a reduced effect on adjacent patterns. The reinforcement pattern may also be used to adjust the pattern density. Accordingly, a malfunction of the device may be prevented, performance may be improved, and a higher degree of integration may be provided.

Similarly, in some embodiments, the first filler cell FC1 may include a second reinforcement pattern B, and the second reinforcement pattern B may include a rectangular shape including an empty space. For example, the empty space inside the second reinforcement pattern B may have a rectangular shape. The second reinforcement pattern B may have a second height H2 in the second direction Y. The second reinforcement pattern B may have a fourth width W4 in the second direction Y. The second reinforcement pattern B may be electrically connected to the second power rail PR2. A size of the second power rail PR2 that may conduct a current may increase by the fourth width W4, in addition to the second width W2 of the second power rail PR2. That is, a voltage drop across the second power rail PR3 may be reduced by increasing the cross-sectional area of the channel of the second power rail PR2 through which the current flows. Also, in some embodiments, the third width W3 and/or the fourth width W4 may be selected to mitigate the voltage drop phenomenon.

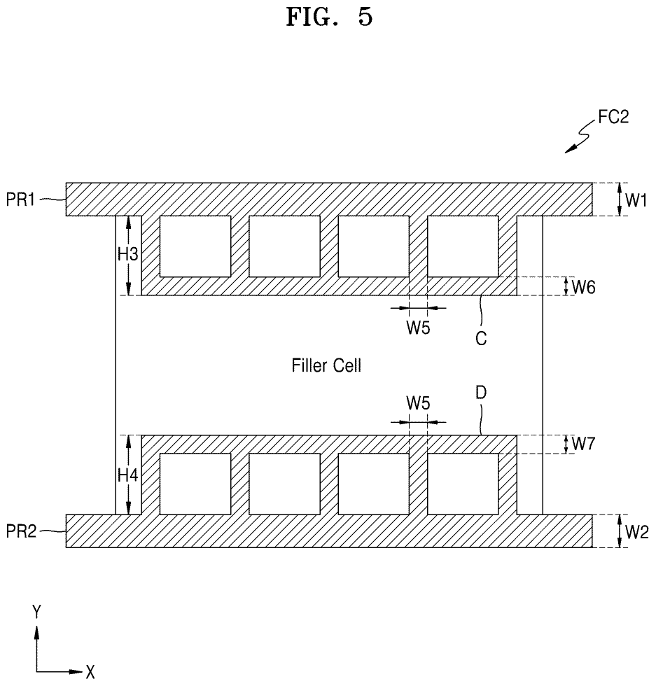

FIG. 5 is a plan view illustrating another structure of a filler cell according to an embodiment.

Referring to FIG. 4 and FIG. 5, the second filler cell FC2 is similarly positioned between the first power rail PR1 having the first width W1 and the second power rail PR2 having the second width W2. Hereinafter, a description of the same or similar parts discussed in connection with the first filler cell FC1 of FIG. 4 may be omitted.

In some embodiments, the second filler cell FC2 may include a third reinforcement pattern C. As shown, the third reinforcement pattern C may include a lattice pattern. The third reinforcement pattern C may be connected to the first power rail PR1 at three or more distinct points, which may thereby form the lattice pattern. The lattice pattern may have a third height H3 in the second direction Y. For example, the lattice pattern of the third reinforcement pattern C may have a rectangular lattice pattern. The third reinforcement pattern C may be electrically connected to the first power rail PR1. As a result, a size of a channel through which current flows may be increased by a fifth width W5 and a sixth width W6, in addition to the first width W1. That is, through the third reinforcement pattern C connected to the first power rail PR1, a cross-sectional area of the channel through which the current flows may be increased.

As shown, since the lattice-shaped pattern of the third reinforcement pattern C may increase the cross-sectional area of the channel through which the current flows (e.g., an increase due to lattice patterns corresponding to the fifth width W5), the voltage drop phenomenon may be mitigated. Also, a pattern density of a device may be adjusted using a dummy pattern including the lattice shape. Furthermore, by properly combining a lattice-shaped pattern and a rectangular-shaped pattern and placing the patterns in a filler cell, an overall pattern density may be more precisely controlled.

Similarly, in some embodiments, the second filler cell FC2 may include a fourth reinforcement pattern D. The fourth reinforcement pattern D may include a lattice pattern having a fourth height H4. For example, the lattice pattern of the fourth reinforcement pattern D may be based on a rectangular lattice pattern. The fourth reinforcement pattern D may be electrically connected to the second power rail PR2, through which a size of a channel through which the current flows may be increased by the fifth width W5 and the seventh width W7. That is, through the fourth reinforcement pattern D, the cross-sectional area of the channel through which the current flows may be increased. As such, a voltage drop across the first power rail PR1 and the second power rail PR2 may be reduced by adding the third reinforcement pattern C and/or the fourth reinforcement pattern D. Also, in some embodiments, the third height H3 and/or the fourth height H4 may be selected to mitigate the voltage drop phenomenon.

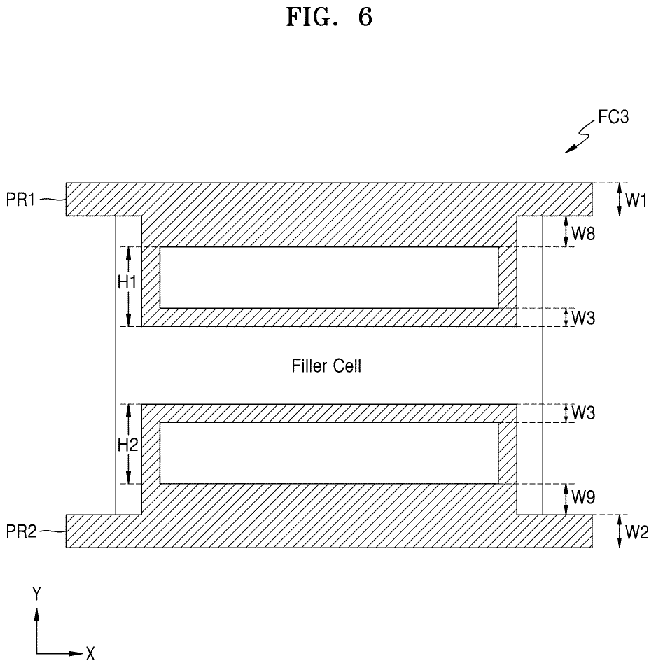

FIG. 6 is a plan view illustrating structures of a power rail and a filler cell according to an embodiment.

Referring to FIG. 4 and FIG. 6, the third filler cell FC3 may be between the first power rail PR1 and the second power rail PR2 extending in the first direction X. The first power rail PR1 and the second power rail PR2 may have a first width W1 and a second width W2, respectively. The first width W1 and the second width W2 may have a same value or have different values. Also, as shown in FIG. 4, the third filler cell FC3 may include a first reinforcement pattern A and/or a second reinforcement pattern B. Hereinafter, a description of the same or similar parts discussed in connection with the first filler cell FC1 of FIG. 4 may be omitted.

In some embodiments, the first power rail PR1 may be reinforced as a method of increasing a size of a channel through which a current flows to reduce a voltage drop. That is, the width of the first power rail PR1 in the second direction Y may not be constant and may be implemented with various values along a length of the power rail in the first direction X. For example, a first portion of the first power rail PR1 corresponding to the third filler cell FC3 may have a width increased by an eighth width W8 in the second direction Y, as shown, to create a wider aisle area. In this way, as a size of the power rail increases, that is, as the cross-sectional area of the channel through which the current flows increases as described herein, a power loss (e.g., IR drop phenomenon) due to a resistance of the power rail may decrease. In other words, since the resistance of the first power rail PR1 may be decreased by increasing the width of the first power rail PR1 by the eighth width W8, a power loss that may occur due to the first power rail PR1 may be decreased.

When a reinforcement pattern (e.g., a first reinforcement pattern A) is included in the third filler cell FC3, in addition to a reinforcement of the first power rail PR1 itself, as shown, the cross-sectional area of the channel through which the current flows may be increased and the voltage drop phenomenon may be mitigated. Accordingly, power may be uniformly supplied to elements in the circuit to prevent malfunction of the device. In addition, power consumption may be reduced, and/or efficiency may be increased by lowering the power supply voltage Vdd supplied to the circuit.

As described herein, the empty space in the reinforcement pattern of the filler cell may be used to reduce the effect on adjacent patterns and adjust the pattern density of the device.

Similarly, in some embodiments, the width of the second power rail PR2 in the second direction Y may be implemented with various values along a length of the power rail in the first direction X. For example, a part of the second power rail PR2 corresponding to the third filler cell FC3 may have a width increased by a ninth width W9 in the second direction Y, as shown. In this case, the cross-sectional area of the channel through which the current flows may be increased by the ninth width W9 and the resistance of the second power rail PR2 may be decreased. Accordingly, power loss that may occur due to the resistance of the second power rail PR2 may be reduced. Also, for example, when a reinforcement pattern (e.g., a second reinforcement pattern B) is included in the third filler cell FC3, in addition to reinforcement of the second power rail PR2 itself, as shown, the cross-sectional area of the channel through which the current flows may be increased and the voltage drop phenomenon may be mitigated.

In should be understood that the reinforcement pattern described in connection with the third filler cell FC3 is not limited thereto. For example, the values of the first height H1, the second height H2, the third width W3, the eighth width W8, and the nineth width W9 of the first reinforcement pattern A and the second reinforcement pattern B may have different values from those of the first filler cell FC1. Furthermore, third width W3, the eighth width W8, and the nineth width W9 may have the same value or different values. In addition, the reinforcement pattern included in the third filler cell FC3 is not limited thereto and may be replaced with reinforcement patterns having various shapes.

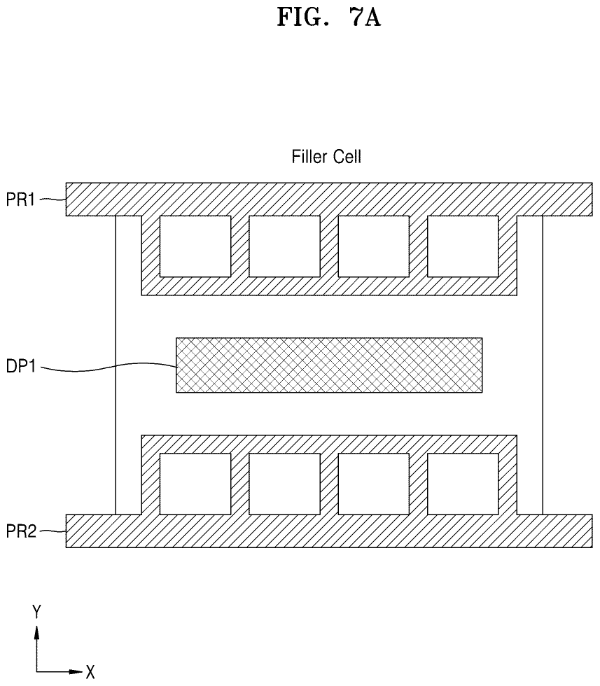

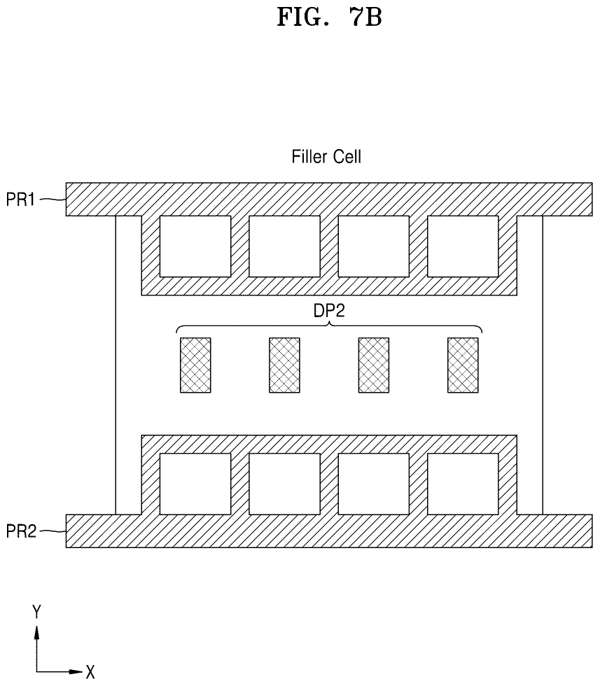

FIG. 7A and FIG. 7B are plan views for explaining a filler cell including a dummy pattern according to an embodiment.

Referring to FIG. 5, FIG. 7A, and FIG. 7B, a filler cell according to an embodiment may include a first dummy pattern DP1 or a second dummy pattern DP2. For example, the filler cells in these drawings may be filler cells in which the first dummy pattern DP1 or the second dummy pattern DP2 is added to the second filler cell FC2 including the lattice pattern as described with respect to FIG. 5.

In some embodiments, the first dummy pattern DP1 may be a pattern that has a height in the second direction Y and a width in the first direction X, as shown. In some embodiments, the second dummy pattern DP2 may be a pattern that extends in the second direction Y. As such, the dummy pattern included in the filler cell may be a pattern extending in the first direction X or the second direction Y. Using the first dummy pattern DP1 and the second dummy pattern DP2 as described herein, uniform process conditions may be maintained for an entire wafer or substrate in an actual process. For example, the first dummy pattern DP1 and the second dummy pattern DP2 may be used to adjust the pattern density. Similarly, the first dummy pattern DP1 and the second dummy pattern DP2 may be used to enhance effects (e.g., planarization effect, heat treatment effect, etc.) in various processes. Accordingly, functionally improved logic elements may be formed.

In some embodiments, since the first dummy pattern DP1 and the second dummy pattern DP2 may be electrically separated from other semiconductor elements, the dummy patterns may be configured not to directly affect functions of other elements in the device. Also, the first dummy pattern DP1 and the second dummy pattern DP2 may be insulated from the first power rail PR1 and the second power rail PR2 and may not perform a direct electrical function within a circuit.

In some embodiments, the first dummy pattern DP1 and the second dummy pattern DP2 may have a similar shape and/or pattern density to patterns disposed in the circuit. For example, the first dummy pattern DP1 and the second dummy pattern DP2 may be patterns designed and arranged corresponding to pattern densities of adjacent logic cells (e.g., standard cells), and may be substantially the same in shape and/or pattern density as the patterns of the circuit.

However, the dummy pattern included in the filler cell is not limited to the examples of FIG. 7A and FIG. 7B. That is, the dummy pattern included in the filler cell may be implemented in various ways to improve uniformity in a process for a wafer or substrate, and/or function of an element. For example, the position and/or shape of the dummy pattern may be selected to adjust the pattern density. In addition, the reinforcement pattern included in the filler cell is not limited to examples described herein. That is, for example, as shown in FIG. 5, the values of the third height H3, the fourth height H4, the fifth width W5, the sixth width W6, and the seventh width W7 of the third reinforcement pattern C and the fourth reinforcement pattern D, which are lattice patterns, may have different values from the value of the second filler cell FC2. Furthermore, the third height H3, the fourth height H4 may have the same value or different values. Similarly, the fifth width W5, the sixth width W6, and the seventh width W7 may have the same value or different values. Moreover, the reinforcement pattern included in the filler cell is not limited to such a lattice pattern, and may be replaced with reinforcement patterns having various shapes.

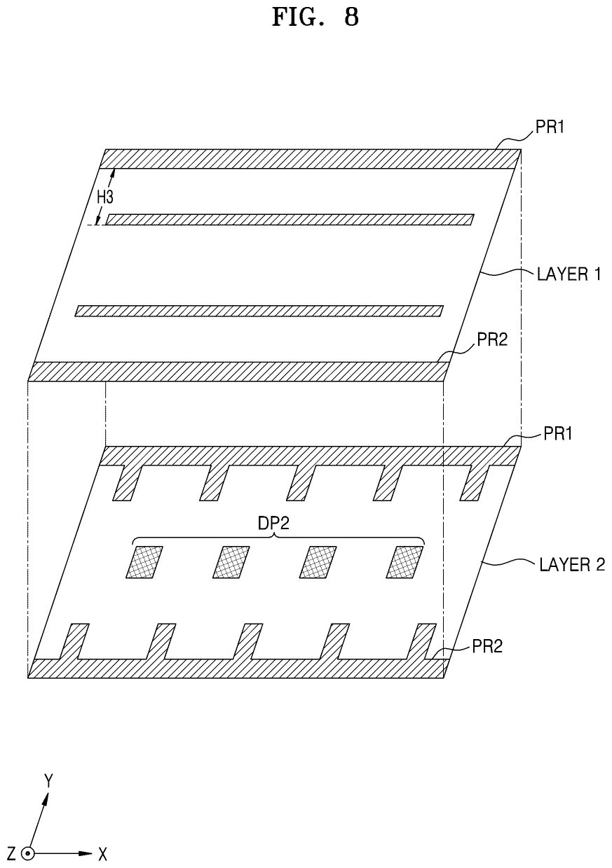

FIG. 8 is a diagram illustrating a structure of layers of a semiconductor device according to an embodiment.

Referring to FIG. 5, FIG. 7B, and FIG. 8, in some embodiments, a reinforcement pattern and a dummy pattern included in a filler cell may be located on different layers. For example, the filler cell may include the third reinforcement pattern C and the second dummy pattern DP2 shown in FIG. 5 formed based on different layers.

For example, a first portion of the third reinforcement pattern C may be positioned on one layer, and a second portion of the third reinforcement pattern C may be positioned on another layer. While not shown, Similarly, a first portion of the second dummy pattern DP2 may be positioned on one layer, and a second portion of the second dummy pattern DP may be positioned on another layer. In one embodiment, a horizontal portion of the third reinforcement pattern C extending in the first direction X and the portion of the second dummy pattern DP2 extending in the first direction X may be located in the first layer LAYER 1. Since the second dummy pattern DP2 includes only the pattern extending in the second direction Y, the dummy pattern configuration may not exist on the first layer LAYER 1. Further, the portion of the third reinforcement pattern C extending in the second direction Y and the second dummy pattern DP2 may be located in the second layer LAYER 2. By locating portions the reinforcement pattern and/or the dummy pattern on different layers, a pattern density may be adjusted, or design rules may be met, for example.

Methods of implementing the reinforcement pattern and the dummy pattern in different layers are not limited thereto. That is, a method of dividing reinforcement patterns and dummy patterns among different layers may be implemented in various ways.

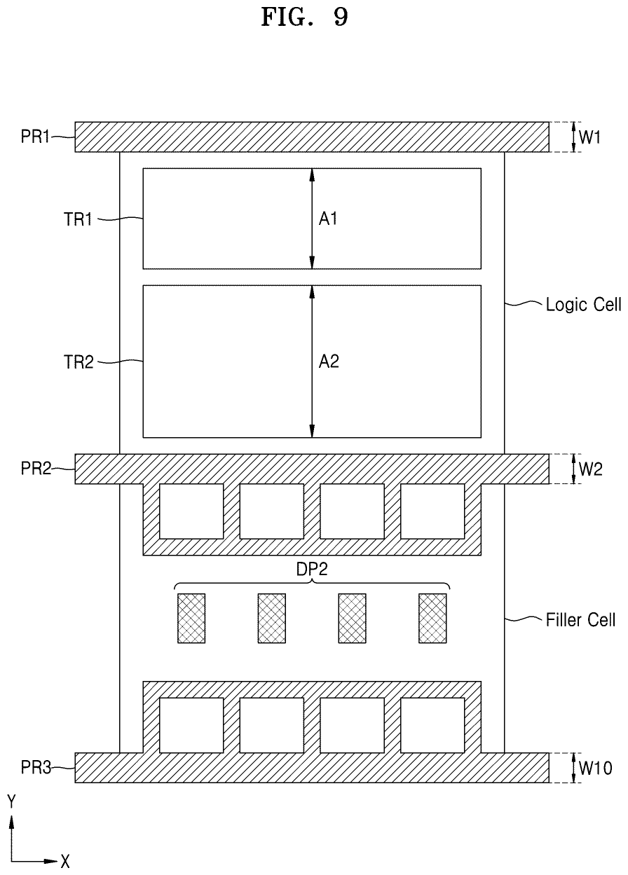

FIG. 9 is a plan view illustrating a structure of adjacent cells according to an embodiment.

Referring to FIG. 9, a cell having a stacked structure may be provided. Specifically, a first power rail PR1, a second power rail PR2, and a third power rail PR3 may be provided on a substrate. The first power rail PR1, a second power rail PR2, and the third power rail may be sequentially spaced apart from each other in the second direction Y. For example, the first power rail PR1 and the third power rail PR3 may be provided with the power supply voltage Vdd, and the second power rail PR2 may be provided with the ground voltage Vss. A logic cell may be located between the first power rail PR1 and the second power rail PR2, and a filler cell may have a cell structure positioned between the second power rail PR2 and the third power rail PR3. The logic cell and the filler cell may be adjacent to each other in the second direction Y. As shown, the first transistor region TR1 and the second transistor region TR2 may be included in the logic cell, and the third reinforcement pattern C and the second dummy pattern DP2 may be included in the filler cell. The stacked structure is not limited thereto, and a logic cell may include various logic elements, and a filler cell may also include various reinforcement patterns and/or dummy patterns.

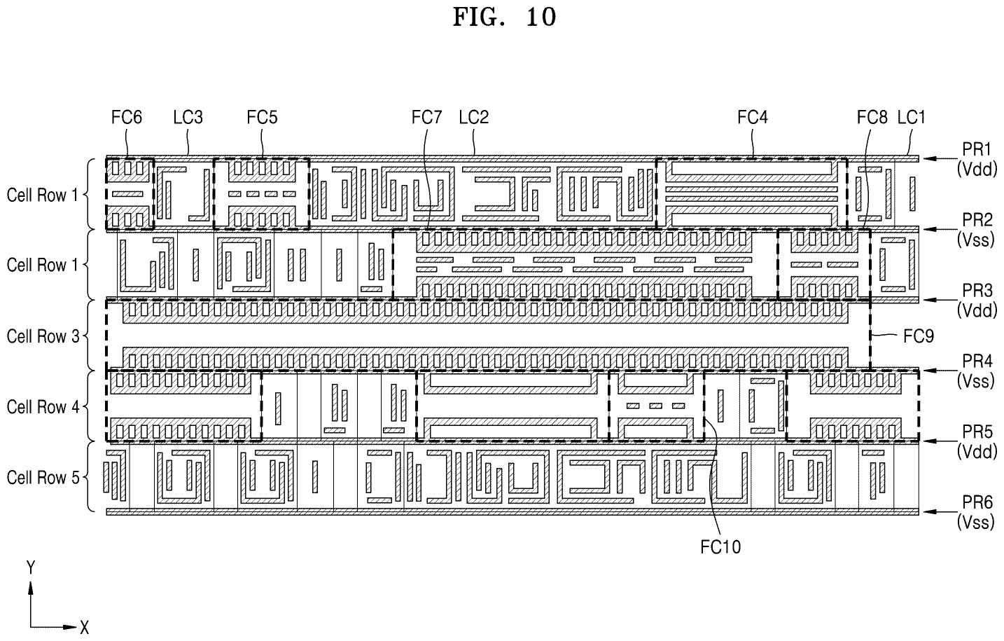

FIG. 10 is a plan view for explaining a semiconductor device having a structure of adjacent cells according to an embodiment.

Referring to FIG. 4, FIG. 5, FIG. 6, FIG. 7A, FIG. 7B, FIG. 9 and FIG. 10, a semiconductor device including a plurality of cell rows Cell Row 1 to Cell Row 5 may be provided according to an embodiment. The plurality of cell rows Cell Row 1 to Cell Row 5 may be spaced apart from each other in the second direction Y and may extend in the first direction X. A plurality of power rails PR1 to PR6 may be provided to supply voltages to the plurality of cell rows Cell Row 1 to Cell Row 5. In some embodiments, a first cell row Cell Row 1 may include a first logic cell LC1, a second logic cell LC2, and a third logic cell LC3, and may include a fourth filler cell FC4, a fifth filler cell FC5, and a sixth filler cell FC6. Each cell may have various lengths in the first direction X. The first to third logic cells LC1 to LC3 may include elements for performing certain functions in a circuit. The fourth filler cell FC4 may include the first reinforcement pattern A and the second reinforcement pattern B shown in FIG. 4, and include a dummy pattern extending in parallel in the first direction X. The fifth filler cell FC5 may include the third reinforcement pattern C and the fourth reinforcement pattern D shown in FIG. 5, and may include dummy patterns spaced apart and extending in the first direction X. Similarly, the sixth filler cell FC6, a seventh filler cell FC7, an eighth filler cell FC8, a nineth filler cell FC9, and a tenth filler cell FC10 may also include at least one of the first to fourth reinforcement patterns A to D, and may additionally include dummy patterns for uniformity and performance. As such, a plurality of filler cells may be located around the logic cells. The plurality of filler cells may reduce a power loss across the power rails through a reinforcement pattern. Further, a pattern density may be adjusted through a dummy pattern(s) of the plurality of filler cells.

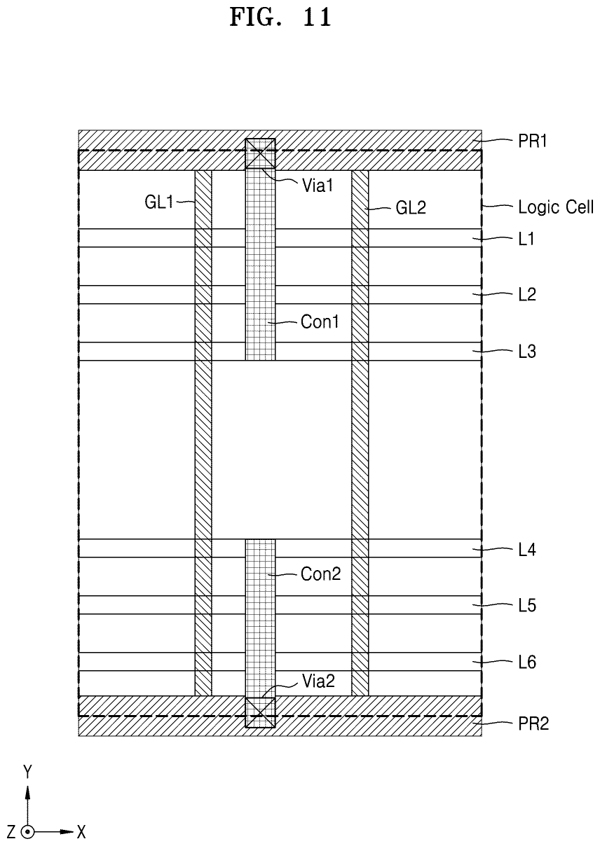

FIG. 11 is a plan view illustrating a logic cell including a transistor configuration according to an embodiment.

Referring to FIG. 11, a circuit may include logic cells having cell boundaries as shown. In an embodiment, a plurality of wiring layers L1 to L6 may be located in a logic cell. It should be understood that the logic cell depicted in FIG. 11 is exemplary and not limiting, and the logic cell may include various other configurations, and the number of wiring layers formed in the logic cell may be implemented in various ways. For example, a logic cell may include a semiconductor, such as silicon (Si) or germanium (Ge), or a compound semiconductor, such as SiGe, silicon carbide (SiC), gallium arsenide (GaAs), indium arsenide (InAs), or indium phosphide (InP). Alternatively, a conductive region, for example, a well doped with impurities or a structure doped with impurities, may be included. For example, an inside of the logic cell may include an N-well formed on a substrate and doped with an N-type impurity, or may be a substrate doped with a P-type impurity.

The logic cell may include a plurality of gate lines, for example, a first gate line GL1 and a second gate line GL2, extending parallel to each other in the second direction Y and spaced apart from each other in the first direction X. The plurality of gate lines may be disposed on a logic cell to form a transistor. For example, each of the plurality of gate lines may form a PMOS transistor or an NMOS transistor.

In some embodiments, at a cell boundary of a logic cell, a first power rail PR1 and a second power rail PR2 extending in parallel in the first direction X may be disposed to supply power to the logic cells. As depicted in FIG. 11, the first power rail PR1 and the second power rail PR2 may be disposed at the cell boundary of the logic cell, but is not limited thereto. For example, at least one of the first power rail PR1 and the second power rail PR2 may be disposed inside the logic cell, and the number of power rails may vary. In addition, the size and/or shape of the first power rail PR1 and/or the second power rail PR2 may be configured in various ways. Elements inside the logic cell may receive a positive power voltage from the first power rail PR1 and a ground voltage (or negative power voltage) from the second power rail PR2. For example, the first wiring layer L1, the second wiring layer L2, and the third wiring layer L3 may be connected to the first power rail PR1 through the first contact Con1 and the first via Via1 to receive a positive power supply voltage. The fourth wiring layer L4, the fifth wiring layer L5, and the sixth wiring layer L6 may be connected to the second power rail PR2 through the second contact Con2 and the second via Via2 to receive a ground voltage.

In some embodiments, the first power rail PR1 and the second power rail PR2 may include a metal material, such as tungsten (W) or cobalt (Co), polysilicon doped with impurities, or SiGe. For example, the first power rail PR1 may include polysilicon doped with N-type impurities, and the second power rail PR2 may include polysilicon doped with P-type impurities. The logic cell may further include additional patterns for transistors and routing depending on a desired function and/or based on a structure of the integrated circuit. For example, the logic cell may further include patterns formed on a plurality of metal layers.

While inventive concepts have been particularly shown and described with reference to embodiments thereof, it will be understood that various changes in form and details may be made therein without departing from the spirit and scope of the following claims.

What is claimed is:

1. A semiconductor device comprising:
a plurality of logic cells disposed in a first direction;
a plurality of filler cells disposed in the first direction;
a power rail extending in the first direction and electrically connected to the plurality of logic cells; and
a reinforcement pattern disposed in at least one of the plurality of filler cells and electrically connected to the power rail,
wherein the reinforcement pattern comprises a lattice pattern,
wherein the reinforcement pattern is electrically connected to the power rail at a plurality of distinct points.

2. The semiconductor device of claim 1, wherein the lattice pattern is electrically connected to the power rail at least three points.

3. The semiconductor device of claim 1, wherein a portion of the power rail parallel to the reinforcement pattern has a first width and a portion of the power rail that is not corresponded to the reinforcement pattern has a second width that is less than the first width.

4. The semiconductor device of claim 1, wherein at least one of the plurality of filler cells comprises a dummy pattern.

5. The semiconductor device of claim 4, wherein the dummy pattern is insulated from the power rail.

6. The semiconductor device of claim 1, further comprising a plurality of layers, wherein a first portion of the reinforcement pattern and a second portion of the reinforcement pattern are located on different layers of the plurality of layers.

7. The semiconductor device of claim 6, wherein the first portion extends in the first direction, and
wherein the second portion extends in a second direction perpendicular to the first direction.

8. A semiconductor device comprising:
a plurality of logic cells disposed in a first direction;
a plurality of filler cells disposed in the first direction; and
a power rail extending in the first direction and electrically connected to the plurality of logic cells,
wherein a width of a first portion of the power rail corresponding to at least one filler cell among the plurality of filler cells in a second direction perpendicular to the first direction is greater than a width of a second portion of the power rail corresponding to the plurality of logic cells in the second direction,
wherein the at least one filler cell includes a reinforcement pattern including an empty space, and
wherein the reinforcement pattern is electrically connected to the power rail.

9. The semiconductor device of claim 8, wherein the empty space of the reinforcement pattern has a rectangular shape.

10. The semiconductor device of claim 8, wherein the at least one filler cell comprises a lattice pattern in which a plurality of reinforcement patterns, including the reinforcement pattern, are arranged in a lattice.

11. The semiconductor device of claim 8, wherein the at least one filler cell includes a dummy pattern.

12. The semiconductor device of claim 11, wherein the dummy pattern is insulated from the power rail.

13. The semiconductor device of claim 11, further comprising a plurality of layers, wherein a first portion of the dummy pattern and a second portion of the dummy pattern are located on different layers of the plurality of layers.

14. The semiconductor device of claim 8, further comprising a plurality of layers, wherein a first portion of the reinforcement pattern and a second portion of the reinforcement pattern are located on different layers of the plurality of layers.

15. The semiconductor device of claim 14, wherein the first portion extends in the first direction, and
wherein the second portion extends in the second direction.

16. A semiconductor device comprising:
a plurality of logic cells extending in a first direction;
a plurality of filler cells extending in the first direction;
a first power rail extending in the first direction and configured to apply a first voltage to the plurality of logic cells; and
a second power rail extending in the first direction, spaced apart from the first power rail in a second direction perpendicular to the first direction, and configured to apply a second voltage to the plurality of logic cells,
wherein the plurality of logic cells and the plurality of filler cells are disposed between the first power rail and the second power rail, in the first direction,
wherein at least one filler cell among the plurality of filler cells comprises at least one reinforcement pattern, and
wherein the at least one reinforcement pattern is electrically connected to one of the first power rail and the second power rail at a plurality of distinct points.

17. The semiconductor device of claim 16, wherein the at least one filler cell comprises a dummy pattern.

18. The semiconductor device of claim 17, wherein the dummy pattern is insulated from the first power rail and the second power rail.

19. The semiconductor device of claim 17, further comprising a plurality of layers, wherein a first portion of the at least one reinforcement pattern and a first portion of the dummy pattern are disposed on a first layer of the plurality of layers, and a second portion of the at least one reinforcement pattern and a second portion of the dummy pattern are disposed on a second layer of the plurality of layers.

20. The semiconductor device of claim 16, further comprising:
a third power rail extending in the first direction and spaced apart from the first power rail and the second power rail in the second direction, and
at least one of an additional logic cell and an additional filler cell is disposed between the second power rail and the third power rail.
